(19) United States
(12) Patent Application Publication
(10) Pub. No.: US 2026/0316216 A1
(43) Pub. Date: Oct. 15, 2026

(54) SUBSTRATE POLISHING APPARATUS AND FILM THICKNESS CALCULATING METHOD

(71) Applicant: EBARA CORPORATION, Tokyo (JP)

(72) Inventors: Keita YAGI, Tokyo (JP); Yuta SUZUKI, Tokyo (JP)

(21) Appl. No.: 19/484,080

(22) PCT Filed: May 7, 2025
(86) PCT No.: PCT/JP2025/016684

§ 371 Date: Nov. 13, 2025

(30) Foreign Application Priority Data
May 8, 2024 (JP) 2024-075597

(51) Int. Cl. B24B 37/013; B24B 37/30; H10P 72/00

(52) U.S. Cl. CPC B24B 37/013; B24B 37/30; H10P 72/0428; H10P 72/0604

(57) ABSTRACT

A substrate polishing apparatus comprises: a polishing table which is provided with an eddy current sensor and constructed to be able to rotate; a polishing head which is arranged to be opposite to the polishing table and constructed to be able to rotate, wherein a substrate can be attached to a surface opposite to the polishing table; and a controller. The controller is constructed for: creating mapping data representing arrangement of one or multiple metal structures locally existing on a surface of or in the inside of a reference substrate, by using output signals that relate to the reference substrate and are from the eddy current sensor; obtaining, during polishing of an object-of-polishing substrate which has metal structure arrangement identical with that of the reference substrate, a profile of output signals of the eddy current sensor when the eddy current sensor passes along a path on a to-be-polished surface of the object-of-polishing substrate; identifying, based on the profile, a path that corresponds to the profile and is defined when the eddy current sensor has passed over the to-be-polished surface of the object-of-polishing substrate; making, based on the mapping data, a judgment as to whether a metal structure exists on the identified path on the object-of-polishing substrate; correcting the profile of the output signals, that relate to the object-of-polishing substrate and are from the eddy current sensor, to reduce a signa value of a position judged as that where the metal structure exists; and calculating film thickness of the object-of-polishing substrate, based on the corrected profile of the output signals of the eddy current sensor.

### TECHNICAL FIELD

The present invention relates to a substrate polishing apparatus and a film thickness calculating method.

### BACKGROUND ART

There is a CMP (Chemical Mechanical Polishing) apparatus in apparatuses for manufacturing semiconductor devices. A representative CMP apparatus comprises a polishing table to which a polishing pad is attached, and a polishing head to which a substrate is attached. In the representative CMP apparatus, a substrate is polished by supplying a polishing liquid to the polishing pad, and rotating, in the state that the polishing pad and the substrate are in contact with each other, at least one of the polishing table and the polishing head.

### CITATION LIST

### Patent Literature

PTL 1: Japanese Patent Application Public Disclosure No. 2021-058955

### SUMMARY OF INVENTION

### Technical Problem

It is possible to use an eddy current sensor for measuring, during polishing of a substrate, thickness of a film which is an object of polishing. The eddy current sensor is installed in a polishing table, for example. The eddy current sensor moves along a path on a surface of a substrate while a polishing table is being rotated, and measures film thickness at respective points on the path (for example, refer to Patent Literature 1). However, in the case that a metal structure, which has been arranged locally in a substrate, exists in addition to a film (a metal film) which is an object of polishing, it becomes difficult, due to an effect therefrom, to accurately measure thickness, that should be measured originally, of the film

### Solution to Problem

According to an embodiment, a substrate polishing apparatus is provided, and the substrate polishing apparatus comprises: a polishing table which is provided with an eddy current sensor and constructed to be able to rotate; a polishing head which is arranged to be opposite to the polishing table and constructed to be able to rotate, wherein a substrate can be attached to a surface opposite to the polishing table; and a controller: wherein the controller is constructed for creating mapping data representing arrangement of one or multiple metal structures locally existing on a surface of or in the inside of a reference substrate, by using output signals that relate to the reference substrate and are from the eddy current sensor; obtaining, during polishing of an object-of-polishing substrate which has metal structure arrangement identical with that of the reference substrate, a profile of output signals of the eddy current sensor when the eddy current sensor passes along a path on a to-be-polished surface of the object-of-polishing substrate; identifying, based on the profile, a path that corresponds to the profile and is defined when the eddy current sensor has passed over the to-be-polished surface of the object-of-polishing substrate; making, based on the mapping data, a judgment as to whether a metal structure exists on the identified path on the object-of-polishing substrate; correcting the profile of the output signals, that relate to the object-of-polishing substrate and are from the eddy current sensor, to reduce a signa value of a position judged as that where the metal structure exists; and calculating film thickness of the object-of-polishing substrate, based on the corrected profile of the output signals of the eddy current sensor.

### BRIEF DESCRIPTION OF DRAWINGS

FIG. 1 is a front view of a substrate polishing apparatus according to an embodiment.

FIG. 2 is a cross-sectional schematic diagram showing a structure of an example substrate which is an object to be polished by a substrate polishing apparatus.

FIG. 3 is a flow chart showing an outline of operation of a substrate polishing apparatus according to an embodiment.

FIG. 4 is a flow chart showing an algorithm of a method according to an embodiment of the present invention.

FIG. 5 is a flow chart showing an algorithm of a method according to an embodiment of the present invention.

FIG. 6 is a schematic drawing showing example paths of an eddy current sensor which passes over a substrate.

FIG. 7 is an example of a sensor output map with respect to a reference substrate.

FIG. 8 is a conceptual diagram of a process for correcting a position of a maximum value (or a minimum value) in a sensor output map.

FIG. 9 is an example of mapping data.

FIG. 10 is a drawing used for explaining a correction process for a profile of output signals of an eddy current sensor.

FIG. 11 is a flow chart showing a process for identifying a path of an eddy current sensor.

FIG. 12 is an example of a sensor output map with respect to a substrate which is an object of polishing.

FIG. 13 is an example of a profile of output signals of an eddy current sensor.

FIG. 14 is an example of a profile cut out from a sensor output map.

### DESCRIPTION OF EMBODIMENTS

In the following description, embodiments of the present invention will be explained with reference to the figures. In the figures that will be explained in the following description, a reference symbol assigned to one component is also assigned to the other component if the other component is the same as or corresponds to the one component, and overlapping explanation of these components will be omitted.

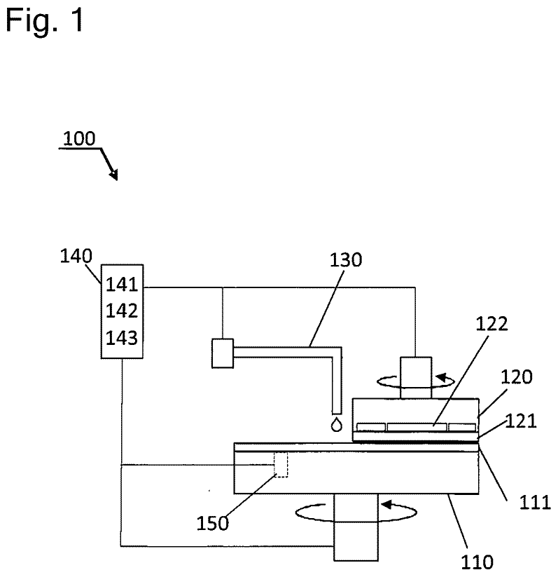

FIG. 1 is a front view of a substrate polishing apparatus 100 according to an embodiment. The substrate polishing apparatus 100 shown in FIG. 1 is a CMP (Chemical Mechanical Polishing) apparatus. It should be reminded that the substrate polishing apparatus 100 is not limited to a CMP apparatus. The substrate polishing apparatus 100 may be any apparatus which polishes a substrate by rotating a polishing table in which an eddy current sensor has been installed.

The CMP apparatus 100 comprises a polishing table 110, a polishing head 120, and a liquid supplying mechanism 130. The CMP apparatus 100 further comprises a controller 140 for controlling respective components. The controller 140 may comprise, for example, a storage device 141, a processor 142, and an input/output device 143.

A polishing pad 111 is installed in an attachable/detachable manner on a top surface of the polishing table 110. In this regard, the top surface of the polishing table 110 refers to a surface, in the polishing table 110, opposite to the polishing head 120. Accordingly, the top surface of the polishing table 110 is not limited to a surface in a position in a vertically upward direction. The polishing head 120 is installed in such a manner that it is in a position opposite to the polishing table 110. A substrate 121 is attached in an attachable/detachable manner to a surface which is in the polishing head 120 and positioned to be opposite to the polishing table 110. The liquid supplying mechanism 130 is constructed to supply a polishing liquid such as slurry or the like to the polishing pad 111. In this regard, the liquid supplying mechanism 130 may be constructed to supply a cleaning liquid, a chemical solution, or the like, in addition to the polishing liquid.

The CMP apparatus 100 is able to bring the substrate 121 into contact with the polishing pad 111, by moving the polishing head 120 downward by operating an up-and-down motion mechanism which is not shown in the figures. In this regard, the up-and-down motion mechanism may be able to move the polishing table 110 upward and downward. The polishing table 110 and the polishing head 120 are rotated by motors or the like which are not shown in the figures. The CMP apparatus 100 polishes the substrate 121 by rotating, in the state that the substrate 121 and the polishing pad 111 are in contact with each other, both the polishing table 110 and the polishing head 120.

The CMP apparatus 100 may further comprise an air bag 122 which is partitioned into multiple concentric circular sections. The air bag 122 may be installed in the polishing head 120. Additionally or alternatively, the air bag 122 may be installed in the polishing table 110. The air bag 122 is a member for adjusting, with respect each of regions in the substrate 121, a polishing pressure applied to the substrate 121. The air bag 122 is constructed in such a manner that it changes its volume according to the pressure of air introduced into the inside thereof. A fluid other than the air, for example, a nitrogen gas or pure water, may be introduced into the air bag 122.

An eddy current sensor 150 is installed in the inside of the polishing table 110. The eddy current sensor 150 is installed in a position such that the eddy current sensor 150 passes the center of the substrate 121 when the polishing table 110 is rotated during polishing. The eddy current sensor 150 is constructed to induce eddy current in an electrically conductive layer on the surface of the substrate 121. The eddy current sensor 150 is further constructed to output, in response to change in impedance due to a magnetic field generated by the eddy current, a signal corresponding to the thickness of the electrically conductive layer on the surface of the substrate 121. By using the output signal from the eddy current sensor 150, the film thickness of the film, which is the object of polishing, on the surface of the substrate 121 can be obtained.

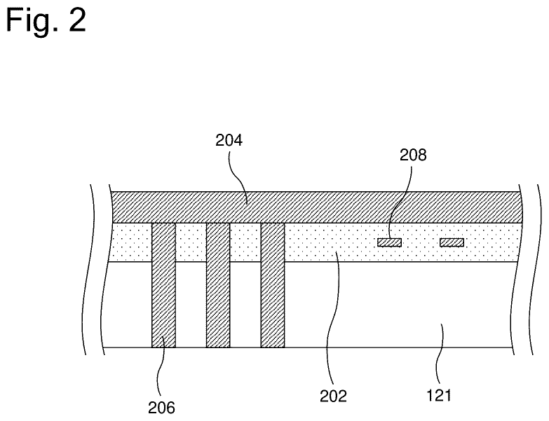

It should be reminded that the matter which influences the output signal of the eddy current sensor 150 is not limited to a film which is exposed on the topmost surface of the substrate 121 (a film formed over the whole topmost surface of the substrate 121) and is an object of polishing. FIG. 2 is a cross-sectional schematic diagram showing a structure of an example substrate 121 which is an object to be polished by the substrate polishing apparatus 100. As shown in FIG. 2, a dielectric film (for example, a film comprising SiO₂ or the like) 202 is formed on the whole top surface of the example substrate 121, and, further, a metal film (for example, a film comprising Cu or the like) 204 is formed above the dielectric film 202 to cover it. The metal film 204 is a film which is positioned on the topmost surface of the substrate 121 and is an object of polishing. Further, the substrate 121 may comprise one or multiple through-electrodes 206 which allow electrical conduction between one surface and the other surface of the substrate 121. Further, a metal wire 208 may be embedded in the dielectric film 202 on the substrate 121. When the eddy current sensor 150 passes over a position above or close to a through-electrode 206 or a metal wire 208 such as that explained above, eddy current is also induced in the above metal structure(s), and the output signal of the eddy current sensor 150 is influenced thereby; and, accordingly, the value of the signal changes from that of an output signal of the eddy current sensor 150 obtained when the eddy current sensor 150 has passed over a region on the substrate 121 where no trough-electrode 206 and no metal wire 208 exists. That is, the through-electrode 206 or the metal wire 208 which is a metal structure formed locally in the substrate 121 may become a cause of generation of noise in an output signal of the eddy current sensor 150. It should be reminded that the metal structures are not limited to the through-electrode 206 and the metal wire 208 embedded in the dielectric film 202 which have been explained above, and, in addition thereto, they may also include a wire exposed on the topmost surface of the substrate 121 and a via, for example.

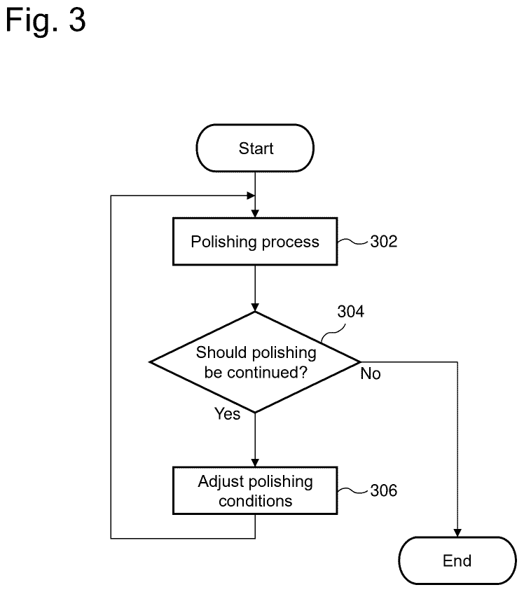

FIG. 3 is a flow chart showing an outline of operation of the substrate polishing apparatus 100 according to an embodiment.

In step 302, a polishing process is performed. Specifically, the substrate 121 is attached to the polishing head 120, and slurry is supplied from the liquid supplying mechanism 130. In the state that the substrate 121 is pressed against the polishing table 110 by the polishing head 120, both the polishing table 110 and the polishing head 120 are rotated to polish the substrate 121. During polishing, a film thickness map, that shows distribution, in the substrate surface, of film thicknesses of a film (for example, the metal film 204 in FIG. 2), which is the object of polishing, on the substrate 121 is created based on output signals from the eddy current sensor 150. Creating of the film thickness map will be explained later in detail. The polishing process in step 302 is continued until a predetermined condition to terminate the polishing process is satisfied, for example, until a preset polishing time, that has been set for polishing the film, which is an object of polishing, by a desired quantity thereof, elapses. After completion of the polishing process in step 302, the operation proceeds to step 304.

In step 304, based on the created film thickness map explained above, a judgment as to whether polishing of the substrate 121 should be continued further is made. For example, a judgment as to whether a desired film thickness or film thickness profile has been achieved in the whole surface of the substrate 121 or in at least part of the substrate 121 is made. In the case that the desired film thickness or film thickness profile has not been achieved, the operation proceeds to step 306 to continue polishing of the substrate 121. On the other hand, in the case that the desired film thickness or film thickness profile has been achieved, the operation of the substrate polishing apparatus 100 is terminated.

In step 306, a polishing condition(s) of the polishing process is adjusted. For example, based on the film thickness map, a duration of time that is to be spent for performing additional polishing is set. Further, based on the film thickness map, the controller 140 may increase or decrease internal pressure of the air bag 122 to increase the polishing pressure in a region where the film thickness is thick (i.e., the region where the degree of progress in polishing is low) or decrease the polishing pressure in a region where the film thickness is thin (i.e., the region where the degree of progress in polishing is high). By adopting the above control, the states of polishing of the substrate 121 can be made uniform. In accordance with the polishing condition(s) adjusted as explained above, the polishing process in step 302 is performed again.

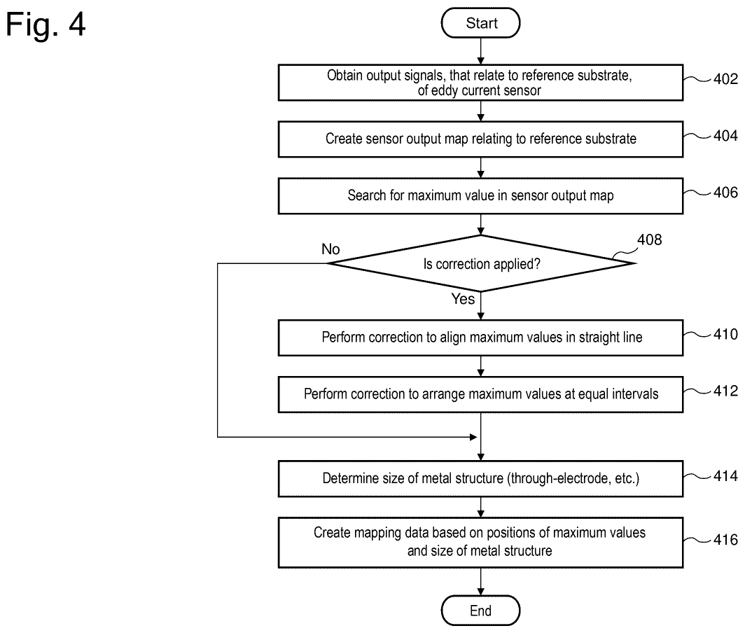

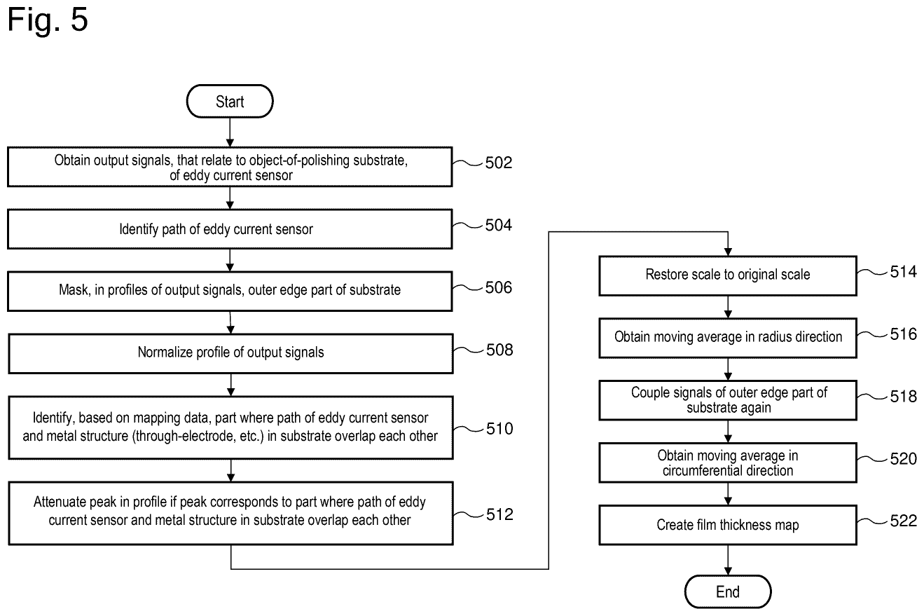

Each of FIG. 4 and FIG. 5 is a flow chart showing an algorithm of a method for calculating film thickness, according to an embodiment of the present invention, by which noise that is generated due to a local metal structure(s) in the substrate 121 and included in an output signal of the eddy current sensor 150 can be removed or reduced. The present method comprises a step, that is performed as preparation operation, for creating mapping data that represents arrangement of one or multiple metal structures which locally exist on a surface of or in a substrate (FIG. 4), and a step for precisely calculating thickness of the film on the substrate by correcting an output signal(s) of the eddy current sensor 150 by using the mapping data created by performing the preparation operation. The process in each of the flow charts may be that performed by a processor (for example, the processor 142 in the controller 140).

First, a process for creating mapping data will be explained with reference to the flowchart in FIG. 4. In this preparation operation step, a “reference substrate” is used. The reference substrate is a substrate which comprises no metal film on the surface thereof. For example, in the case of the example substrate 121 (hereinafter, an “object-of-polishing substrate”) in FIG. 2, a substrate which is formed by removing the metal film 204 from the whole surface to thereby make the dielectric film 202 expose on the topmost surface is a reference substrate (hereinafter, a “reference substrate 121′” for convenience sake). For example, one or multiple object-of-polishing substrates, which have been polished antecedently, in multiple object-of-polishing substrates 121 of the same kind (i.e., the object-of-polishing substrates manufactured by performing the same manufacture steps) may be used as a reference substrate(s) 121′. In this regard, “substrates of the same kind” means “substrates with respect to which the wiring patterns formed thereon are identical with one another at least in design.”

In step 402, output signals of the eddy current sensor 150 are obtained with respect to the reference substrate 121′. Specifically, output signals are obtained from the eddy current sensor 150, while both the polishing head 120, to which the reference substrate 121′ has been attached, and the polishing table 110 are being rotated, wherein each of the polishing head 120 and the polishing table 110 is rotated at its predetermined rotational speed. The eddy current sensor 150 moves, in terms of the reference substrate 121′ (i.e., when viewed from the reference substrate 121′), in such a manner that it draws an arc-shaped path(s) according to a ratio between the rotational speed of the polishing table 110 and the rotational speed of the polishing head 120. During each single rotation of the polishing table 110, the eddy current sensor 150 crosses the surface of the reference substrate 121′ along an ark-shaped path having a predetermined curvature that is determined based on the rotational speed of the polishing table 110 and the rotational speed of the polishing head 120; and, during a next single rotation of the polishing table 110, the eddy current sensor 150 passes along a path corresponding to a different arc that is an arc having a curvature that is the same as the curvature in the case of the last single rotation. Accordingly, signal values at respective points on the multiple ark-shaped paths are obtained successively from the eddy current sensor 150. In this regard, since accurate mapping data cannot be created if polishing of a substrate progresses when step 402 is being performed, it is desirable that water, instead of slurry, be supplied from the liquid supplying mechanism 130 when step 402 is being performed (i.e., step 402 be performed as a water polishing process). By adopting the above construction, signal values corresponding to the multiple paths on the reference substrate 121′ can be obtained from the eddy current sensor 150, in the state that polishing of a substrate does not progress.

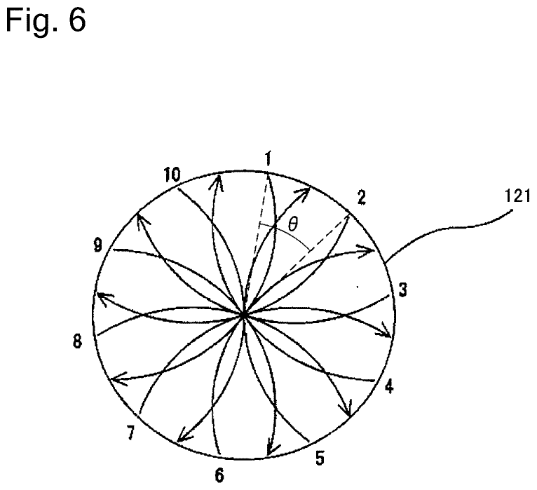

FIG. 6 is a schematic drawing showing example paths of the eddy current sensor 150 which passes over the substrate 121 (for example, the reference substrate 121′). In the figure, each arc-shaped curved arrow represents a path on that the eddy current sensor 150 moves, and a direction that the eddy current sensor 150 moves on the path. Further, a symbols “1”-“10” in the figure show the order of the paths on that the eddy current sensor 150 moves. The eddy current sensor 150 outputs signal values of respective points on the paths, when the polishing table 110 and the polishing head 120 are rotated and the eddy current sensor 150 is accordingly moved along the paths, in the order of the paths “1”-“10,” on the surface of the substrate 121.

It should be reminded that, in the example in FIG. 6, the angle interval θ between adjacent paths is set to 36 degrees; accordingly, after the polishing table 110 rotates ten times, the eddy current sensor 150 moves along the same path that the eddy current sensor 150 has moved along previously (the path next to the path “10” is the path “1”). That is, the number of paths that the eddy current sensor 150 moves along is at most 10 in this example. On the other hand, it is preferable, for increasing the number of points measured by the eddy current sensor 150, to have a sufficiently large number of paths that the eddy current sensor 150 moves along; accordingly, for example, the angle interval θ between adjacent paths may be set to that less than 10 degrees, to that less than 5 degrees, preferably, or to that less than 1 degree, more preferably. The angle interval θ between adjacent paths may be set in such a manner that the points measured by the eddy current sensor 150 are densely arranged in the substrate 121. The angle interval θ between adjacent paths can be set in an optional manner, by selecting a combination of the rotational speed of the polishing table 110 and the rotational speed of the polishing head 120.

Next, in step 404, a sensor output map for the reference substrate 121′ is created by using output signals of the eddy current sensor 150 obtained in step 402. The sensor output map is a map that represents distribution of magnitude of output signals of the eddy current sensor 150 on the whole surface of the substrate 121 (the reference substrate 121′ in this case). As explained above, with respect to each of the multiple paths on the reference substrate 121′, signal values from the eddy current sensor 150 at respective measurement points on the path are obtained, and a sensor output map for the reference substrate 121′ can be created by plotting the signal values on an X-Y plane. The X-Y coordinates of each of the measurement points on the path can be specified, based on the shape (curvature) of the path that is determined based on the rotational speed of the polishing table 110 and the rotational speed of the polishing head 120, or based on signals from an encoder installed in a motor(s) for rotating the polishing table 110 and the polishing head 120.

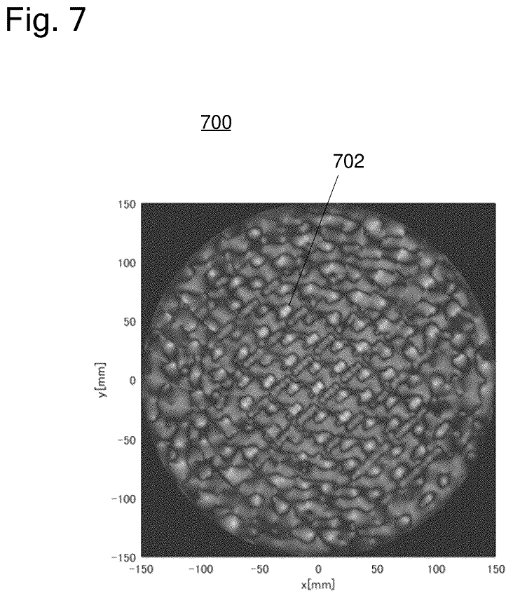

FIG. 7 is an example of a sensor output map 700 with respect to the reference substrate 121′, that is created in accordance with step 404. In this example, distribution of the signal values, at respective measurement points, obtained by the eddy current sensor 150 is shown in a light and shade manner. The sensor output map 700 comprises multiple bright spots 702 that are distributed in the plane of the reference substrate 121′. These bright spots 702 are regions where signal values from the eddy current sensor 150 are large, and corresponding to local metal structures (the through-electrodes 206, the metal wires 208, and so on in FIG. 2) constructed in the reference substrate 121′. It should be reminded that, for example, the through-electrodes 206 are often arranged regularly (for example, the respective through-electrodes 206 are arranged linearly and/or at equal intervals), due to designing of end products (for example, semiconductor chips) manufactured by using the substrate 121.

Next, in step 406, maximum values (or minimum values) are searched for in the sensor output map created in step 404, and the positions (i.e., X-Y coordinates) of the found maximum values (or minimum values) are temporarily stored. An appropriate well-known method can be applied as the algorithm for searching for maximum values (or minimum values), and detailed explanation relating thereto will be omitted herein.

Next, in the case that a correction process is to be applied to a position(s) of a maximum value(s) (or minimum value(s)) (Yes in step 408), the operation proceeds to step 410. In step 410, positions of the respective maximum values (or minimum values) are corrected in such a manner that the multiple maximum values (or minimum values) found in step 406 are arranged to be aligned in a straight line. In step 412 that follows the above step, the positions of the respective maximum values (or minimum values) are corrected in such a manner that the multiple maximum values (or minimum values) found in step 406 are arranged at equal intervals in the X-Y plane. Either one of step 410 and step 412 may be omitted. Further, a correction process for interpolating a lost maximum value(s) (or minimum value(s)) may be performed in step 412.

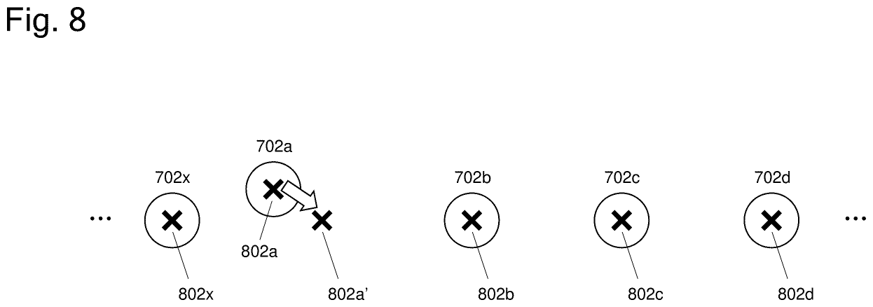

FIG. 8 is a conceptual diagram used for explaining processes, that are performed in step 410 and step 412, for correcting a position of a maximum value (or a minimum value). As explained above, for example, in the case that the substrate 121 (the reference substrate 121′) in which multiple through-electrodes 206 are arranged linearly and at equal intervals is used, it can be expected that the bright spots 702 in the sensor output map 700 created in step 404 are arranged to be precisely aligned in a straight line and at equal intervals, if the paths of the eddy current sensor 150 precisely cross over all of the through-electrodes 206 explained above. However, in the case that the eddy current sensor 150 has passed over a position that is somewhat shifted from a position of a through-electrode 206, the position of a spot 702, that is in the sensor output map 700 and corresponds to the through-electrode 206, deviates from an expected position in positions aligned in a straight line and at equal intervals. In FIG. 8, a spot 702a represents such a positionally shifted spot. On the other hand, other spots 702b, 702c, and so on are those that are not positionally shifted, i.e., are aligned in a straight line and at equal intervals. In step 410 and step 412, based on positions 802b, 802c, and so on of the maximum values that correspond to the not-positionally-shifted spots 702b, 702c, and so on, respectively, a position 802a of a maximum value, that corresponds to the positionally shifted spot 702a and has been identified in step 406, is corrected to be changed to a corrected position 802a′ in the positions aligned in a straight line and at equal intervals. According to the above process, positions of local metal structures (the through-electrodes 206, the metal wires 208, and so on) constructed in the reference substrate 121′ can be identified correctly, irrespective of paths of the eddy current sensor 150.

Next, in step 414, the size of the local metal structure in the reference substrate 121′ is determined. For example, in the case that the metal structure is a through-electrode 206, a diameter of the through-electrode 206 is determined. On the other hand, in the case that the metal structure is a metal wire 208, the width and/or the length of the wire may be determined. For example, the diameter of the through-electrode 206 may be determined in advance, based on the spot size of the eddy current sensor 150 (i.e., the size of an area in which the eddy current sensor 150 can detect a magnetic field), a clearance between the eddy current sensor 150 and the reference substrate 121′, an actual size of the through-electrode 206 in the reference substrate 121′ (known design dimensions), or the like. In a different mode, the diameter of the through-electrode 206 may be determined based on the size of a bright spot 702 in the sensor output map 700 created in step 404. For example, the size of the bright spot 702 in the sensor output map 700 may be defined as that of a region in which signal values are equal to or greater than a predetermined value, or that of a region in which signal values are equal to or greater than a value corresponding to a predetermined percentage of each maximum value in the sensor output map 700.

Next, in step 416, mapping data that represents arrangement of local metal structures in the reference substrate 121′ is created, based on the positions of the maximum values (or the minimum values) that are in the sensor output map and identified in step 406 (or the positions of the maximum values (or the minimum values) corrected in step 410 and step 412) and the size of the metal structure determined in step 414. For example, multiple circles may be defined in such a manner that the centers of the circles correspond to the positions 802a′, 802b, 802c, and so on of the respective maximum values, each being represented by symbol X in FIG. 8, and the diameter of the through-electrode 206 determined in step 414 corresponds to a radius of each circle; and the mapping data may be created in such a manner that a value of “1” is assigned to the part in the inside of the circle, that is defined as explained above, and a value of “0” is assigned to the part in the outside of the circle. As a result, mapping data corresponding to the reference substrate 121′ comprising multiple through-electrodes 206 can be obtained.

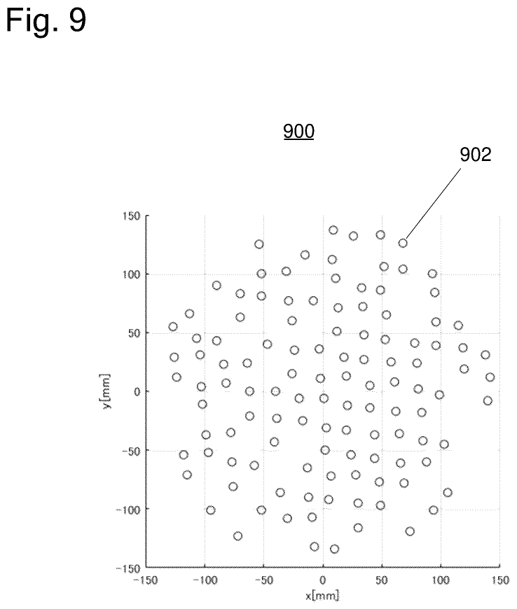

FIG. 9 is an example of mapping data created in the manner explained above. Mapping data 900 comprises coordinate values (X-Y coordinates) of respective points in an X-Y plane that represents the surface of the substrate 121, and values for discriminating whether the respective points on the substrate 121 correspond to metal structures (the through-electrodes 206, the metal wires 208, or the like). In the example mapping data 900 in FIG. 9, each of points inside multiple black circles 902 has a value of “1,” and this shows that regions corresponding thereto in the substrate 121 correspond to the through-electrodes 206. On the other hand, each of points outside the black circles 902 has a value of “0.” By using the above-explained mapping data 900, positions of local metal structures (for example, the through-electrodes 206, the metal wires 208, or the like) constructed in the substrate 121 can be identified.

Next, processes for correcting output signals of the eddy current sensor 150 by using the mapping data, and calculating thickness of a film on the substrate will be explained with reference to the flow chart in FIG. 5. It should be reminded that a substrate used in the processes is an “object-of-polishing substrate” 121 (for example, a substrate such as that shown in FIG. 2, i.e., a substrate which has a metal film 204, which is an object of polishing, formed on a surface thereof) rather than a reference substrate 121′.

First, in step 502, output signals of the eddy current sensor 150, with respect to the object-of-polishing substrate 121, are obtained. Specifically, output signals are obtained from the eddy current sensor 150, while both the polishing head 120, to which the object-of-polishing substrate 121 has been attached, and the polishing table 110 are being rotated, wherein each of the polishing head 120 and the polishing table 110 is rotated at its predetermined rotational speed. Step 502 is basically similar to step 402 in the flow chart in FIG. 4 explained above; and the eddy current sensor 150 moves along arc-shaped paths on the surface of the object-of-polishing substrate 121 while the polishing table 110 and the polishing head 120 are being rotated, and, when the eddy current sensor 150 is moving, signal values corresponding to respective points on the paths on the object-of-polishing substrate 121 are successively obtained from the eddy current sensor 150. In the following description, a series of signal values obtained from the eddy current sensor 150 when the eddy current sensor 150 has moved along a single path will be referred to as a “profile” of output signals of the eddy current sensor 150. It should be reminded that step 502 may be performed during the time when the object-of-polishing substrate 121 is being polished in the polishing process in step 302 in the flow chart in FIG. 3 explained above.

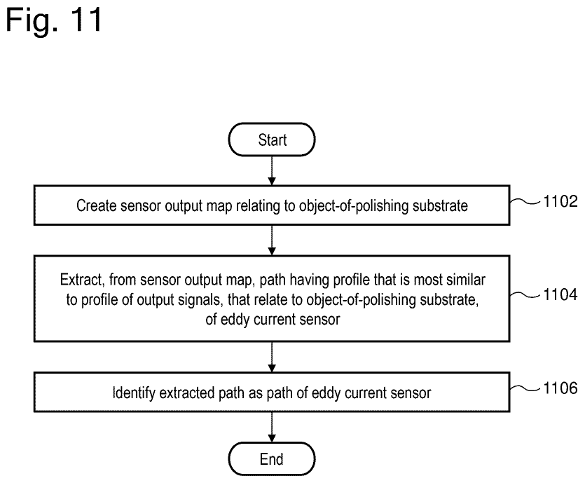

Next, in step 504, a path on the object-of-polishing substrate 121, along that the eddy current sensor 150 moved, is identified based on a profile of output signals of the eddy current sensor 150. Details of step 504 will be explained later with reference to FIG. 11.

Next, in step 506, in the profiles of output signals of the eddy current sensor 150 obtained in step 502, parts corresponding to an outer edge part of the substrate 121 (for example, a belt-shaped region extending from an edge of the substrate 121 toward the inner side by several millimeters) are masked. This is because it is preferable to exclude, from values used in calculation performed later, signal values of the eddy current sensor 150 obtained in the outer edge part of the substrate 121, since it is assumed that accuracy of measurement performed by the eddy current sensor 150 in the outer edge part is relatively low.

Next, in step 508, the profiles of output signals of the eddy current sensor 150, that are obtained after application of the process in step 506, are normalized.

Next, in step 510, coordinates of parts of the paths of the eddy current sensor 150 identified in step 504, that overlap the local metal structures (for example, the through-electrodes 206, the metal wires 208, or the like) in the object-of-polishing substrate 121, are extracted based on the mapping data created in the process in the flow chart in FIG. 4. For example, by superimposing the paths of the eddy current sensor 150 on the example mapping data 900 shown in FIG. 9, parts where the paths of the eddy current sensor 150 overlap the local metal structures in the object-of-polishing substrate 121 can be identified. More specifically, in the respective points on the paths of the eddy current sensor 150, the points, each corresponding to the value “1” in the mapping data 900 (i.e., the black circles 902 in FIG. 9), can be extracted as parts where the paths of the eddy current sensor 150 overlap the local metal structures in the object-of-polishing substrate 121.

Next, in step 512, by using the result obtained in step 510, a correction process for the profiles of the output signals of the eddy current sensor 150 is performed. Specifically, signal peaks in a profile of output signals of the eddy current sensor 150 normalized in step 508 is searched for; and judgment as to whether the found peaks correspond to the positions identified in step 510, i.e., the positions where the path of the eddy current sensor 150 and the local metal structures in the object-of-polishing substrate 121 overlap each other, is performed. In the case that the peaks in the profile correspond to the positions of the overlapped parts, the profile of the output signals of the eddy current sensor 150 is corrected by making the peaks in the profile be attenuated (i.e., by reducing the signal values of the peak parts).

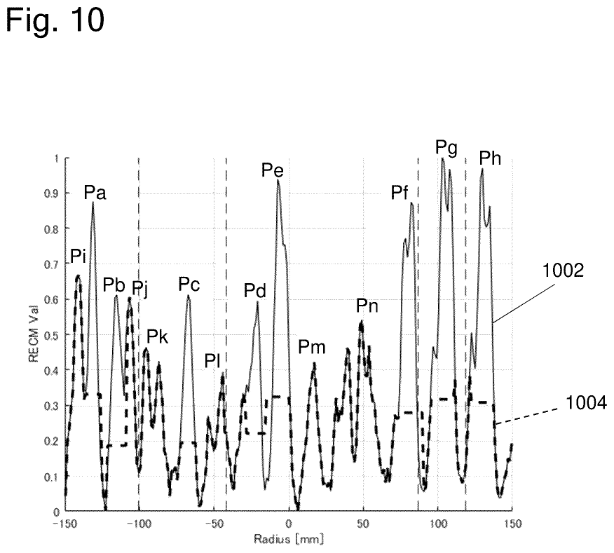

FIG. 10 shows, for assisting understanding of the correction process in step 512, an example including a pre-correction profile and a corrected profile of output signals of the eddy current sensor 150. In the graph in FIG. 10, the horizontal axis represents positions of the eddy current sensor 150 on a path, and the vertical axis represents normalized sensor output signals (i.e., signal values of the eddy current sensor 150 normalized in step 508). In the example in FIG. 10, the pre-correction profile 1002 comprises peaks Pa, Pb, Pc, Pd, Pe, Pf, Pg, and Ph corresponding to parts where the path of the eddy current sensor 150 identified by using the mapping data and the local metal structures in the object-of-polishing substrate 121 overlap each other, and peaks Pi, Pj, Pk, PI, Pm, and Pn that are those other than above peaks. In the corrected profile 1004, signal values at positions adjacent to the positions of the peaks Pa, Pb, Pc, Pd, Pe, Pf, Pg, and Ph are changed to predetermined values smaller than peak values of the peaks, respectively. More specifically, signal values in a region that is adjacent to the position of each of the peaks Pa, Pb, Pc, Pd, Pe, Pf, Pg, and Ph and corresponds to a part where a path of the eddy current sensor 150 and a local metal structures in the object-of-polishing substrate 121 overlap each other (i.e., a region corresponding to value “1” in the mapping data 900) are changed to a predetermined value. For example, the predetermined value may be a value calculated by multiplying a peak value of each peak by an attenuation rate (for example 30%). In this regard, the attenuation rate may be set in such a manner that it becomes larger as the position approaches closer to the center of a peak. On the other hand, the peaks Pi, Pj, Pk, PI, Pm, and Pn are not objects of correction, and are left as they stand in the corrected profile 1004.

As explained above, by correcting, in steps 510 and 512, the profile of the output signals of the eddy current sensor 150 based on the mapping data, noise that is generated due to local metal structures included in an object-of-polishing substrate 121 and added to the output signals of the eddy current sensor 150 can be removed or reduced.

Next, in step 514, for restoring the values normalized in step 508 to the values of the original scale, the profile corrected in step 512 is multiplied by a reciprocal number of the ratio that was used to multiply the signal values of the eddy current sensor 150 when normalization was performed.

Next, in step 516, with respect to the profile processed in step 514, a moving average relating to the direction along the path of the eddy current sensor 150 (i.e., the moving average relating to the direction of the horizontal axis in the graph in FIG. 10) is calculated.

Next, in step 518, signal values corresponding to the outer edge part of the substrate 121 masked in step 506 are coupled again to the profile processed in step 516.

Next, in step 520, a moving average of the profiles, that were processed in step 518 and relate to adjacent multiple paths of the eddy current sensor 150, is calculated. In this regard, the moving average processing in step 516 corresponds to calculation for obtaining a moving average in a radius direction in the substrate 121, and the moving average processing in step 520 corresponds to calculation for obtaining a moving average in a circumferential direction in the substrate 121. By performing the above moving average processing, fine noise existing in the profiles of output signals of the eddy current sensor 150 can be removed.

Next, in step 522, based on the profiles, that have been obtained by performing processing in the steps up to step 520, of signal values relating to the multiple paths (on the whole substrate surface) of the eddy current sensor 150, a film thickness map of the object-of-polishing substrate 121 is created (refer to step 302 in FIG. 3). For example, with respect to each of multiple paths of the eddy current sensor 150, film thickness of each point on the path can be calculated from a profile processed in step 520; and, by plotting the film thickness of each point on an X-Y plane, a film thickness map showing film thickness distribution on the object-of-polishing substrate 121 can be created. As explained above, since noise due to local metal structures in the object-of-polishing substrate 121 has been removed or reduced in the profile processed in step 520, a film thickness map, that is not affected by a through-electrode 206, a metal wire 208, and so on in the object-of-polishing substrate 121 and is precise accordingly, can be obtained.

Next, the process for identifying the path of the eddy current sensor 150 in above-explained step 504 will be explained in detail with reference to a flow chart in FIG. 11.

In step 1102, a sensor output map for the object-of-polishing substrate 121 is created. By performing a method similar to that for creating the sensor output map created in above-explained step 404 in FIG. 4 for the reference substrate 121′, the sensor output map for the object-of-polishing substrate 121 can be created by using output signals of the eddy current sensor 150 with respect to the object-of-polishing substrate 121. For example, the sensor output map for the object-of-polishing substrate 121 can be created in advance by using one or multiple object-of-polishing substrates 121 which are of the same kind as and separated from those used in the process in the flow chart in FIG. 5.

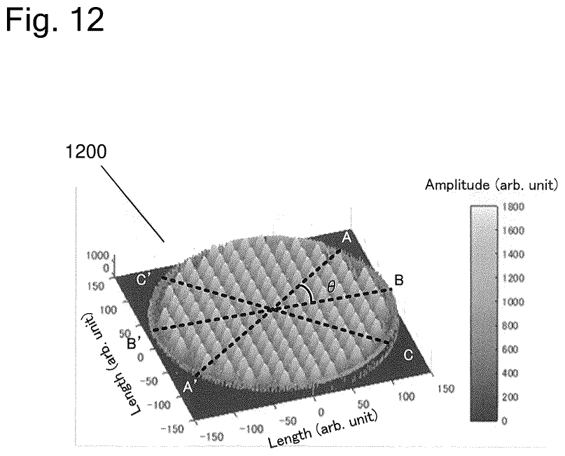

FIG. 12 is an example of a sensor output map 1200 with respect to an object-of-polishing substrate 121. Values of output signals of the eddy current sensor 150, along a line that is drawn on the sensor output map 1200 and has an arbitrarily selected shape (for example, line A-A′ shown in the figure), can be used to form a profile. That is, a profile along an arbitrarily drawn line on the sensor output map 1200 can be calculated from the map.

Next, in step 1104, from the sensor output map that relates to the object-of-polishing substrate 121 and was created in step 1102, a path having a profile that is most similar to a profile of output signals of the eddy current sensor 150 obtained in above-explained step 502 in the flow chart in FIG. 5 (for example, a profile obtained during polishing of the object-of-polishing substrate 121) is extracted. Further, in step 1106, the path extracted from the sensor output map is identified as the path on the object-of-polishing substrate 121 along that the eddy current sensor 150 passed.

For example, by obtaining the total sum of differences between respective signal values of measurement points in a profile relating to a path on the sensor output map created in step 1102 and respective signal values of corresponding measurement points in a profile of output signals of the eddy current sensor 150 obtained in step 502, the degree of similarity between the profiles can be determined. For example, in the case that the total sum of differences is the smallest, it can be judged that the two profiles are most similar to each other. In a different mode, for example, the degree of similarity may be determined by comparing at least one of the peak shape, the peak position, and the peak size in a profile relating to a path on the sensor output map with at least one of the peak shape, the peak position, and the peak size in a profile of output signals of the eddy current sensor 150. Further, any other method for determining the degree of similarity between profiles may be used.

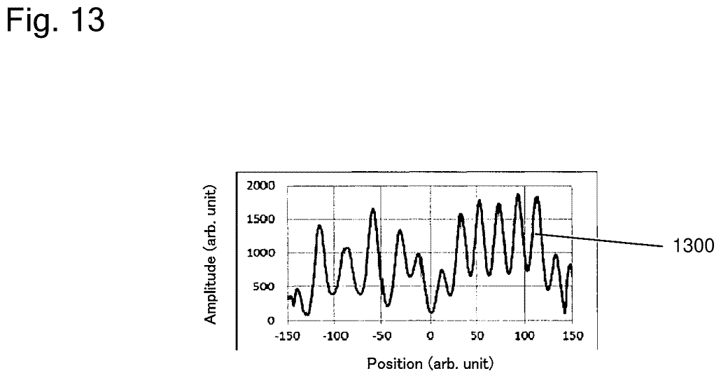

The processes performed in step 1104 and step 1106 will be explained more tangibly with reference to FIG. 12 to FIG. 14. For example, profiles relating to a path A-A′, a path B-B′, and a path C-C′ are extracted from the sensor output map 1200 in FIG. 12. For example, the angle interval θ between adjacent paths may be 0.1 or less than 0.1 degrees, and the number of extracted profiles may be 4 or more than 4. Although the path A-A′ and so on are shown as straight lines in FIG. 12, the shape of each path may have an arc shape like that of an actual path. In the present case, it is supposed that a profile 1300, such as that shown in FIG. 13, of output signals of the eddy current sensor 150 was obtained in step 502 in the flow chart in FIG. 5.

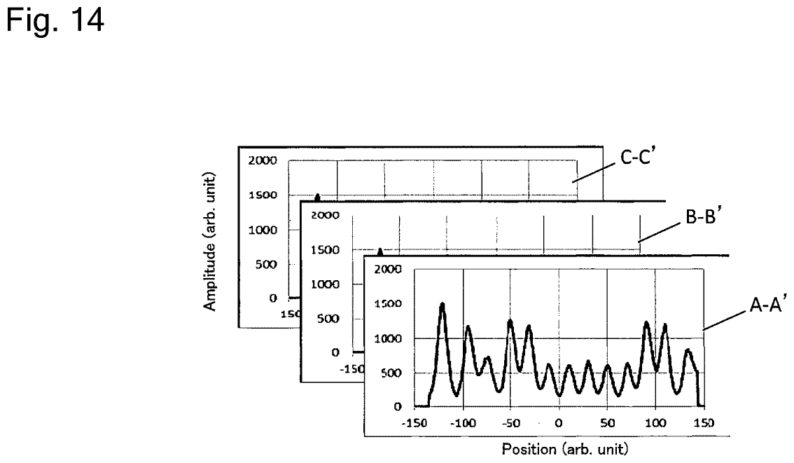

The controller 140 obtains a profile relating to each of paths on the sensor output map 1200. As shown in FIG. 12, there are three paths in this example. Accordingly, in this example, three profiles (a profile A-A′, a profile B-B′, and a profile C-C′) are obtained from the sensor output map 1200 as shown in FIG. 14. In this regard, it should be understood that the profiles in FIG. 14 are not those representing precisely-reproduced versions of the profiles obtained from the sensor output map 1200 in FIG. 12.

The controller 140 identifies, by using an arbitrarily selected method for comparing the degrees of similarity, a profile that is most similar to the profile 1300 of the output signals of the eddy current sensor 150. For example, the controller 140 is able to normalize the profile 1300 of the output signals of the eddy current sensor 150 and the profile A-A′, the profile B-B′, and the profile C-C′ obtained from the sensor output map 1200, and, thereafter, based on the magnitude of the respective mean square errors relating thereto, calculate the degrees of similarity. In this example, it is supposed that the profile C-C′ is most similar to the profile 1300 of the output signals of the eddy current sensor 150. The controller 140 can identify the path C-C′ corresponding to the profile C-C′ as the path on the object-of-polishing substrate 121 along that the eddy current sensor 150 passed.

In the above description, embodiments of the present invention have been explained based on some examples; and, in this regard, the above-explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

100 Substrate polishing apparatus
110 Polishing table
111 Polishing pad
120 Polishing head
121 Substrate
122 Air bag
130 Liquid supplying mechanism
140 Controller
141 Storage device
142 Processor
143 Input/output device
150 Eddy current sensor
202 Dielectric film
204 Metal film
206 Through-electrode
208 Metal wire

1. A substrate polishing apparatus comprising:
a polishing table which is provided with an eddy current sensor and constructed to be able to rotate;
a polishing head which is arranged to be opposite to the polishing table and constructed to be able to rotate, wherein a substrate can be attached to a surface opposite to the polishing table; and
a controller: wherein
the controller is constructed for
creating mapping data representing arrangement of one or multiple metal structures locally existing on a surface of or in the inside of a reference substrate, by using output signals that relate to the reference substrate and are from the eddy current sensor;
obtaining, during polishing of an object-of-polishing substrate which has metal structure arrangement identical with that of the reference substrate, a profile of output signals of the eddy current sensor when the eddy current sensor passes along a path on a to-be-polished surface of the object-of-polishing substrate;
identifying, based on the profile, a path that corresponds to the profile and is defined when the eddy current sensor has passed over the to-be-polished surface of the object-of-polishing substrate;
making, based on the mapping data, a judgment as to whether a metal structure exists on the identified path on the object-of-polishing substrate;
correcting the profile of the output signals, that relate to the object-of-polishing substrate and are from the eddy current sensor, to reduce a signa value of a position judged as that where the metal structure exists; and
calculating film thickness of the object-of-polishing substrate, based on the corrected profile of the output signals of the eddy current sensor.

2. The substrate polishing apparatus as recited in claim 1, wherein the process for creating the mapping data comprising a process for correcting a position of each maximum value in multiple maximum values or each minimum value in multiple minimum values in output signals, that relate to the whole surface of the reference substrate and are from the eddy current sensor, in such a manner that the multiple maximum values or the multiple minimum values are aligned in a straight line.

3. The substrate polishing apparatus as recited in claim 1, wherein the process for creating the mapping data comprising a process for correcting a position of each maximum value in multiple maximum values or each minimum value in multiple minimum values in output signals that relate to the whole surface of the reference substrate and are from the eddy current sensor, or performing interpolation relating to the positions, in such a manner that the multiple maximum values or the multiple minimum values are arranged at equal intervals.

4. The substrate polishing apparatus as recited in claim 1, wherein the process for correcting the profile comprises a process for reducing a peak, that is included in multiple peaks included in the profile and corresponds to the position of the metal structure, and an adjacent part near the peak.

5. The substrate polishing apparatus as recited in claim 4, wherein the process for correcting the profile comprises a process for reducing a peak, that is included in multiple peaks included in the profile and corresponds to the position of the metal structure, and an adjacent part near the peak to make them lower than a peak that does not correspond to the metal structure.

6. The substrate polishing apparatus as recited in claim 4, wherein the adjacent part corresponds to the size of the metal structure.

7. The substrate polishing apparatus as recited in claim 1, wherein the reference substrate is a substrate which does not comprise a metal film on the surface of the substrate.

8. The substrate polishing apparatus as recited in claim 1, wherein the object-of-polishing substrate is a substrate which comprises a metal film, which is an object of polishing, on the surface of the substrate.

9. The substrate polishing apparatus as recited in claim 1, wherein the metal structure is a through-electrode or a metal wire formed in a substrate.

10. The substrate polishing apparatus as recited in claim 1, wherein the process for identifying, based on the profile, the path comprises
a process for creating a sensor output map that represents distribution of magnitude of output signals that relate to the whole surface of the object-of-polishing substrate and are from the eddy current sensor, and
a process for extracting, from the sensor output map, a path having a profile that is most similar to the profile obtained during polishing of the object-of-polishing substrate, and identifying the extracted path as the path of the eddy current sensor with respect to the object-of-polishing substrate.

11. The substrate polishing apparatus as recited in claim 1 further comprising
an air bag which is able to adjust polishing pressure applied to the object-of-polishing substrate; wherein
the controller is further constructed to control, based on the calculated film thickness of the object-of-polishing substrate, internal pressure of the air bag.

12. A film thickness calculating method in a substrate polishing apparatus, wherein
the substrate polishing apparatus comprises
a polishing table which is provided with an eddy current sensor and constructed to be able to rotate; and
a polishing head which is arranged to be opposite to the polishing table and constructed to be able to rotate, wherein a substrate can be attached to a surface opposite to the polishing table: and
the method comprises
a step for creating mapping data representing arrangement of one or multiple metal structures locally existing on a surface of or in the inside of a reference substrate, by using output signals that relate to the reference substrate and are from the eddy current sensor;
a step for obtaining, during polishing of an object-of-polishing substrate which has metal structure arrangement identical with that of the reference substrate, a profile of output signals of the eddy current sensor when the eddy current sensor passes along a path on a to-be-polished surface of the object-of-polishing substrate;
a step for identifying, based on the profile, a path that corresponds to the profile and is defined when the eddy current sensor has passed over the to-be-polished surface of the object-of-polishing substrate;
a step for making, based on the mapping data, a judgment as to whether a metal structure exists on the identified path on the object-of-polishing substrate;
a step for correcting the profile of the output signals, that relate to the object-of-polishing substrate and are from the eddy current sensor, to reduce a signa value of a position judged as that where the metal structure exists; and
a step for calculating film thickness of the object-of-polishing substrate, based on the corrected profile of the output signals of the eddy current sensor.
